(19) United States
(12) Patent Application Publication
(10) Pub. No.: US 2026/0293046 A1
(43) Pub. Date: Sep. 24, 2026

(54) Liquid Cooling Module and Connector

(71) Applicant: Tyco Electronics (Shanghai) Co., Ltd., Shanghai (CN)

(72) Inventors: WenYu (Vindy) Liu, Shanghai (CN); Guangming (Suny) Zhao, Shanghai (CN); Yang (Eric) Shi, Shanghai (CN); Jin (Ralf) Zhang, Shanghai (CN)

(73) Assignee: Tyco Electronics (Shanghai) Co., Ltd., Shanghai (CN)

(21) Appl. No.: 19/572,956

(22) Filed: Mar. 20, 2026

(30) Foreign Application Priority Data
Mar. 20, 2025 (CN) 202510337674.9
Dec. 4, 2025 (CN) 202511821711.X

(51) Int. Cl. H05K 7/20; H01R 13/508; H01R 13/6596

(52) U.S. Cl. CPC H05K 7/20272; H01R 13/508; H01R 13/6596; H05K 7/20254

(57) ABSTRACT

A liquid cooling module includes a plurality of liquid cooling plates and a plurality of flexible tubes. The liquid cooling plates are arranged in parallel in a transverse direction. Each liquid cooling plate has an inner chamber accommodating a cooling liquid. The flexible tubes are connected between any two adjacent liquid cooling plates. The inner chambers of any two adjacent liquid cooling plates are connected together by the flexible tubes. The liquid cooling plates are connected via the flexible tubes and have an inlet pipe joint and an outlet pipe joint connected to their inner chambers, so as to form a cooling circuit from the inlet pipe joint to the outlet pipe joint.

### CROSS-REFERENCE TO RELATED APPLICATION

This application claims the benefit of the filing date under 35 U.S.C. § 119(a)-(d) of Chinese Patent Application No. CN 202510337674.9 filed on Mar. 20, 2025, and Chinese Patent Application No. CN 202511821711.X filed on Dec. 4, 2025, the whole disclosure of which is incorporated herein by reference.

### FIELD OF THE INVENTION

The present invention relates to a liquid cooling module and, more particularly, to a liquid cooling module and a connector comprising the liquid cooling module.

### BACKGROUND OF THE INVENTION

A liquid cooling module is usually installed on the top wall of the connector housing to cool the connector. The liquid cooling module includes multiple liquid cooling plates arranged side by side in the transverse direction of the connector housing. An inner chamber is formed in each liquid cooling plate to accommodate the cooling liquid. The liquid cooling plate has two opposite sides in the transverse direction of the connector housing and two opposite ends in the longitudinal direction of the connector housing. A hose joint is formed at one end of each liquid cooling plate to communicate with its inner chamber. There is a hose connected between the hose joints of any two adjacent liquid cooling plates to connect the inner chambers of the two adjacent liquid cooling plates together. In addition, an inlet pipe joint and an outlet pipe joint are respectively formed on one of the ends of the outermost two liquid cooling plates among multiple liquid cooling plates, so that the cooling liquid can flow into the inner chambers of multiple liquid cooling plates through the inlet pipe joint and flow out from the inner chambers of multiple liquid cooling plates through the outlet pipe joint.

The hose connected between the hose joints of adjacent liquid cooling plates needs to be bent into a U-shape, which increases the flow path and resistance of the liquid flow, causing serious pressure loss. In addition, hoses bent into a U-shape are more prone to leakage during long-term use, and the large number of hose joints and hoses can greatly increase the risk of leakage during long-term use.

### SUMMARY OF THE INVENTION

A liquid cooling module includes a plurality of liquid cooling plates and a plurality of flexible tubes. The liquid cooling plates are arranged in parallel in a transverse direction. Each liquid cooling plate has an inner chamber accommodating a cooling liquid. The flexible tubes are connected between any two adjacent liquid cooling plates. The inner chambers of any two adjacent liquid cooling plates are connected together by the flexible tubes. The liquid cooling plates are connected via the flexible tubes and have an inlet pipe joint and an outlet pipe joint connected to their inner chambers, so as to form a cooling circuit from the inlet pipe joint to the outlet pipe joint.

### BRIEF DESCRIPTION OF DRAWINGS

The invention will now be described by way of example with reference to the accompanying figures, of which:

FIG. 1 is a perspective view of a connector according to an exemplary embodiment;

FIG. 2 is an exploded view of the connector of FIG. 1;

FIG. 3 is a longitudinal sectional view of the connector of FIG. 1;

FIG. 4 is a perspective view of a liquid cooling module of the connector of FIG. 1;

FIG. 5 is a horizontal sectional view of the liquid cooling module of FIG. 4;

FIG. 6 is an exploded view of the liquid cooling module of FIG. 4;

FIG. 7 is a perspective view of a liquid cooling plate of the liquid cooling module of FIG. 4;

FIG. 8 is an exploded view of the liquid cooling plate of FIG. 7;

FIG. 9 is a bottom perspective view of the liquid cooling plate of FIG. 7;

FIG. 10 is a perspective view of a liquid cooling module of a connector according to another exemplary embodiment;

FIG. 11 is a horizontal sectional view of the liquid cooling module of FIG. 10;

FIG. 12 is an exploded view of the liquid cooling module of FIG. 10;

FIG. 13 is a perspective view of a liquid cooling module of a connector according to another exemplary embodiment;

FIG. 14 is a horizontal sectional view of the liquid cooling module of FIG. 13;

FIG. 15 is a perspective view of a liquid cooling module of a connector according to another exemplary embodiment;

FIG. 16 is a horizontal sectional view of the liquid cooling module of FIG. 15;

FIG. 17 is a vertical sectional view of the liquid cooling module of FIG. 15;

FIG. 18 is a perspective view of a liquid cooling module of a connector according to another exemplary embodiment;

FIG. 19 is a perspective view of a liquid cooling module of a connector according to another exemplary embodiment;

FIG. 20 is a perspective view of the liquid cooling module of FIG. 19, with a top cover removed; and

FIG. 21 is a vertical sectional view of the liquid cooling module FIG. 19.

### DETAILED DESCRIPTION

Exemplary embodiments of the present disclosure will be described hereinafter in detail with reference to the attached drawings, wherein like reference numerals refer to like elements. The present disclosure may, however, be embodied in many different forms and should not be construed as being limited to the embodiments set forth herein; rather, these embodiments are provided so that the present disclosure will be thorough and complete, and will fully convey the concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

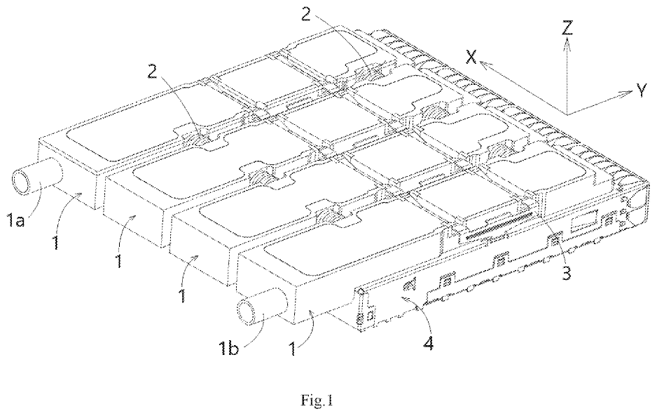

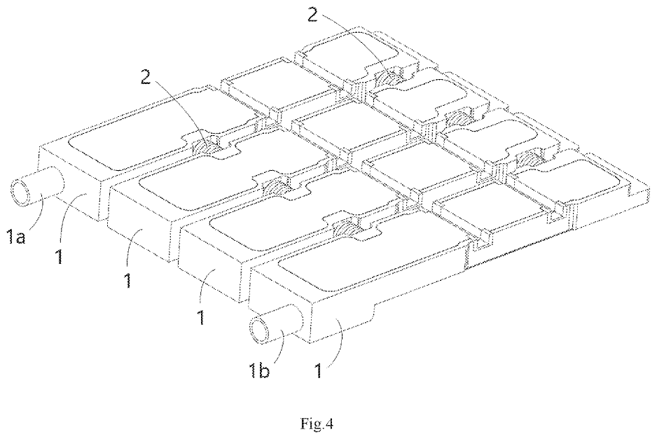

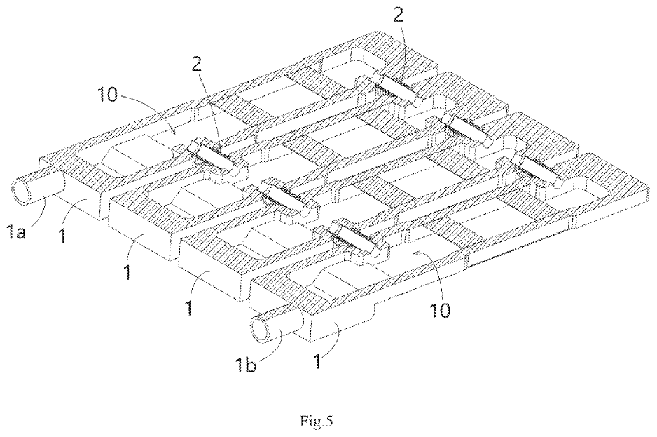

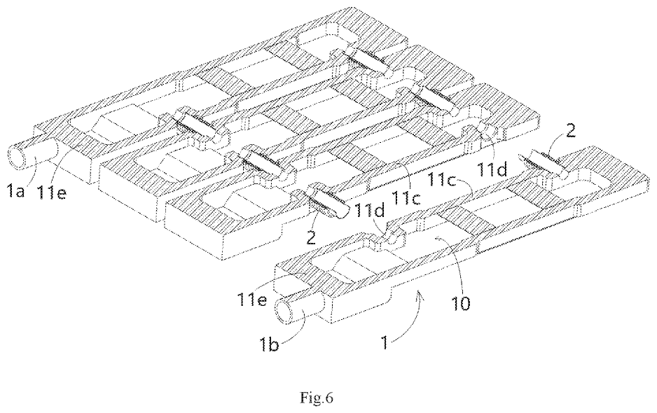

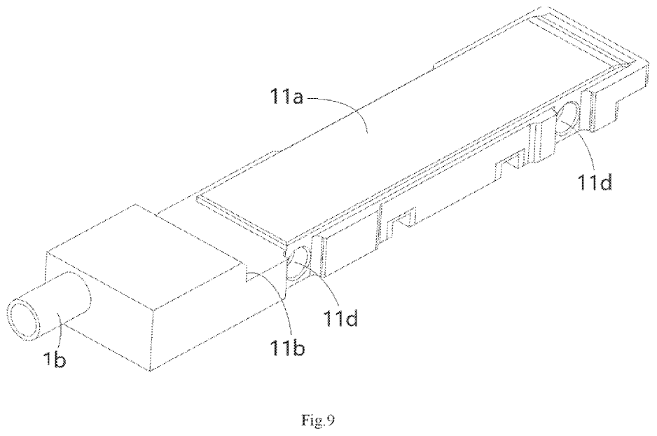

An exemplary embodiment of a liquid cooling module will now be described with reference to FIGS. 1-9. As shown in FIGS. 1-2 and 4-5, the liquid cooling module includes multiple liquid cooling plates 1. The multiple liquid cooling plates 1 are arranged side by side in the transverse direction X of the connector housing 4. As shown in FIGS. 5-6 and 8, the multiple liquid cooling plates 1 each have an inner chamber 10 for accommodating a cooling liquid. The liquid cooling plate 1 has two opposite side walls 11c, as shown in FIG. 6, in the transverse direction X.

As shown in FIGS. 1-2 and 4-6, the liquid cooling module also includes multiple flexible tubes 2. A flexible tube 2 is connected between the side walls 11c of any two adjacent liquid cooling plates 1, so that the inner chambers 10 of any two adjacent liquid cooling plates 1 are connected together by the flexible tube 2. In this way, the inner chambers 10 of the multiple liquid cooling plates 1 can be interconnected through multiple flexible tubes 2. As shown in FIGS. 1 and 4-6, the multiple liquid cooling plates 1 have an inlet pipe joint 1a and an outlet pipe joint 1b connected to their inner chambers 10, so as to form a cooling circuit from the inlet pipe joint 1a, the multiple liquid cooling plates 1 connected via the flexible tubes 2, to the outlet pipe joint 1b.

As shown in FIGS. 1 and 4-6, the inlet pipe joint 1a is formed on one of the outermost liquid cooling plates 1 among multiple liquid cooling plates 1 and is connected to the inner chamber 10 of the liquid cooling plate 1. The outlet pipe joint 1b is formed on the other of the outermost liquid cooling plates 1 among multiple liquid cooling plates 1 and is connected to the inner chamber 10 of the liquid cooling plate 1. The cooling liquid flows into the inner chambers 10 of multiple liquid cooling plates 1 through the inlet pipe joint 1a and flows out from the inner chambers 10 of multiple liquid cooling plates 1 through the outlet pipe joint 1b.

As shown in FIGS. 1-2 and 4-6, due to a small spacing between adjacent liquid cooling plates 1, the flexible tube 2 connected between the side walls 11c of adjacent liquid cooling plates 1 is very short and does not require bending. The present invention can not only shorten the liquid flow path and reduce the liquid flow resistance, but also reduce the risk of cooling liquid leakage.

The flexible tube 2 connected between adjacent liquid cooling plates 1 can elastically deform in the height direction Z perpendicular to the transverse direction X and longitudinal direction Y. Therefore, each liquid cooling plate 1 can independently float a certain amount in the height direction Z, allowing for a certain height difference between adjacent liquid cooling plates 1 in the height direction Z, enabling the present invention to accommodate a certain height difference and expand its application range.

As shown in FIG. 6, the liquid cooling plate 1 has two end walls 11e opposite each other in the longitudinal direction Y perpendicular to the transverse direction X. The inlet pipe joint 1a is formed on the outer side of one end wall 11e of one of the outermost liquid cooling plates 1 among the multiple liquid cooling plates 1, and the outlet pipe joint 1b is formed on the outer side of one end wall 11e of the other of the outermost liquid cooling plates 1 among the multiple liquid cooling plates 1.

As shown in FIGS. 1-2 and 4-6, the flexible tube 2 extends in a straight line along the transverse direction X or in a straight line along a direction inclined at a predetermined angle to the transverse direction X. The flexible tube 2 can be, but is not limited to, various deformable metal flexible tubes, such as corrugated tubes or thin-walled hoses.

As shown in FIGS. 6 and 8-9, a connection hole 11d is formed in the side wall 11c of the liquid cooling plate 1 to communicate with its inner chamber 10. The end of the flexible tube 2 is inserted into the connection hole 11d of the liquid cooling plate 1 and sealingly connected to it. The end of the flexible tube 2 is sealingly connected to the connection hole 11d of the liquid cooling plate 1 through sealant or sealingly welded to the connection hole 11d of the liquid cooling plate 1.

As shown in FIGS. 1-2 and 4-6, two flexible tubes 2 are connected between the side walls 11c of any two adjacent liquid cooling plates 1. One of the two flexible tubes 2 is located near one end of the liquid cooling plate 1, and the other is located near the other end of the liquid cooling plate 1.

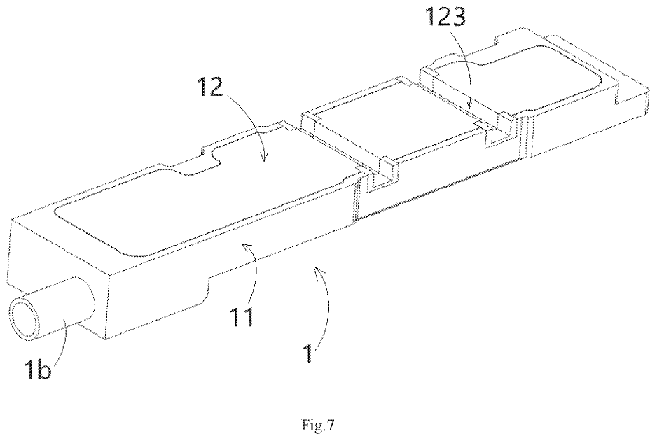

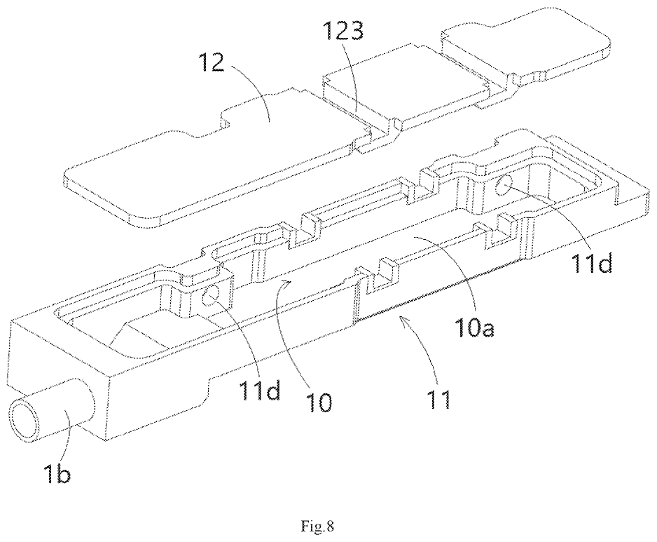

As shown in FIG. 7, the liquid cooling plate 1 includes a base 11 and a top cover 12. The inner chamber 10 is formed in the base 11, and the base 11 has a top opening 10a, as shown in FIG. 8. The top cover 12 is sealingly installed onto the top opening 10a of the base 11. The flexible tube 2 is connected between the side walls 11c of the base 11 of two adjacent liquid cooling plates 1.

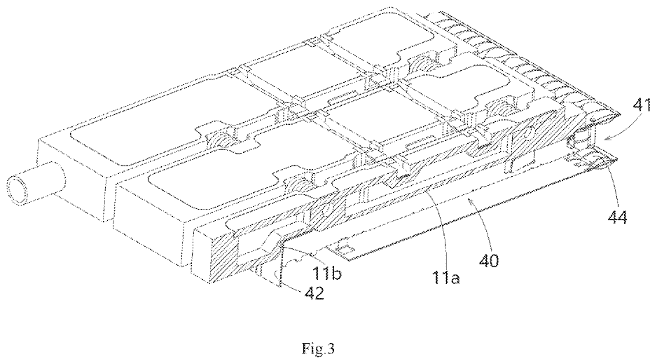

As shown in FIG. 3, a contact protrusion 11a is formed at the bottom of the base 11, which is adapted to protrude into the connector housing 4 through a window 401 on the connector housing 4 to make thermal contact with a mating connector inserted into the connector housing 4.

As shown in FIGS. 7-8, a groove 123 extending in the transverse direction X is formed on the top surface of the top cover 12 of the liquid cooling plate 1, which is used to install an elastic clip 3, so that the liquid cooling plate 1 can be locked to the top wall of the connector housing 4 through the elastic clip 3 installed in the groove 123.

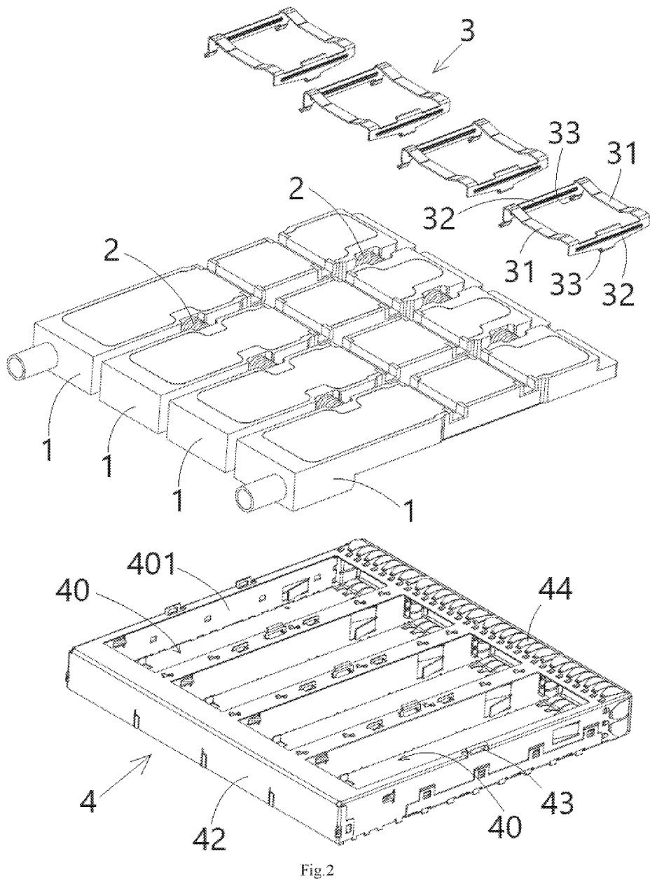

As shown in FIGS. 1-2, the liquid cooling module also includes multiple elastic clips 3. The Multiple elastic clips 3 are respectively installed into the grooves 123 of multiple liquid cooling plates 1, and is used to lock the multiple liquid cooling plates 1 onto the top wall of the connector housing 4 and apply a predetermined pressing force on the liquid cooling plates 1 to ensure reliable thermal contact between the liquid cooling plates 1 and the mating connectors inserted into the connector housing 4.

As shown in FIGS. 7-8, two grooves 123 formed on the top cover 12 of the liquid cooling plate 1 are spaced opposite each other in the longitudinal direction Y. As shown in FIG. 2, the elastic clip 3 includes a pair of elastic crossbeams 31, a pair of longitudinal beams 32, and multiple elastic hooks 33. A pair of elastic crossbeams 31 are respectively accommodated in two grooves 123 of the liquid cooling plate 1. One longitudinal beam 32 is connected between one ends of the pair of elastic crossbeams 31, and the other longitudinal beam 32 is connected between the other ends of the pair of elastic crossbeams 31. The multiple elastic hooks 33 are respectively formed on the pair of longitudinal beams 32. The elastic hook 33 is suitable for engaging with the slot 43 on the connector housing 4.

An exemplary embodiment of a connector will now be described with reference to FIGS. 1-9. As shown in FIGS. 1-2, the connector includes the connector housing 4 and the aforementioned liquid cooling module. The connector housing 4 has multiple insertion cavities 40 arranged side by side in its transverse direction X. The liquid cooling module is installed on the top wall of connector housing 4. Multiple windows 401 corresponding to the multiple insertion cavities 40 are formed on the top wall of the connector housing 4. The contact protrusions 11a of the multiple liquid cooling plates 1 respectively protrude into the multiple insertion cavities 40 through the multiple windows 401 for thermal contact with multiple mating connectors inserted into the multiple insertion cavities 40.

The connector further comprises multiple electrical connection modules, which are respectively installed in the multiple insertion cavities 40 of the connector housing 4. The multiple electrical connection modules are used to mate with multiple mating connectors inserted to achieve electrical connection between the connector and the mating connector.

As shown in FIGS. 2-3, the connector housing 4 has front and rear ends opposite in its longitudinal direction Y, and the insertion cavity 40 has a front port 41 and a rear end wall 42 opposite in the longitudinal direction Y. The mating connector is adapted to be inserted into the insertion cavity 40 of the connector housing 4 from the front port 41 of the insertion cavity 40.

As shown in FIG. 2, a contact spring 44 is installed on the peripheral wall of the front port 41 of the insertion cavity 40, which is used to make electrical contact with an outer shielding shell of the inserted mating connector.

As shown in FIG. 3, a positioning step 11b is formed at the bottom of the rear end of the liquid cooling plate 1. The positioning step 11b is pressed against the rear end wall 42 of the connector housing 4 along the longitudinal direction Y to longitudinally position the liquid cooling plate 1.

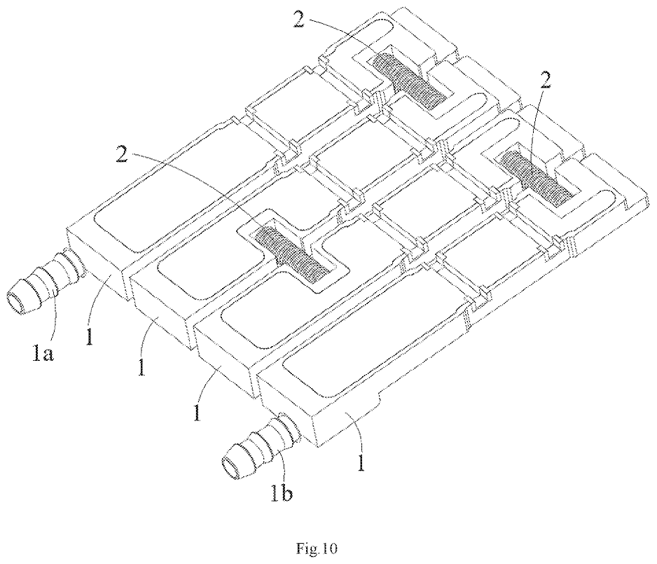

Another exemplary embodiment of a liquid cooling module will now be described with reference to FIGS. 10-12. The difference between the liquid cooling module of the connector shown in FIGS. 10-12 and the liquid cooling module of the connector shown in FIGS. 1-9 mainly lies in the structure of the liquid cooling plate 1. Other technical features are basically the same as those of the liquid cooling module of the connector shown in FIGS. 1-9, which can be referred to as the liquid cooling module of the connector shown in FIGS. 1-9.

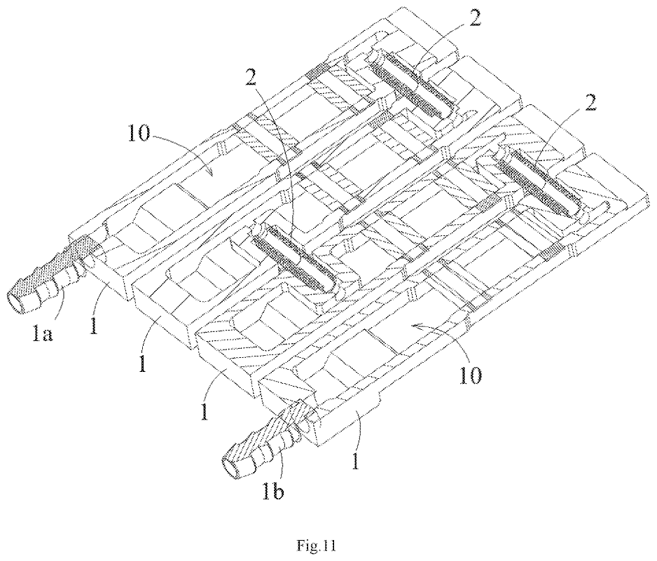

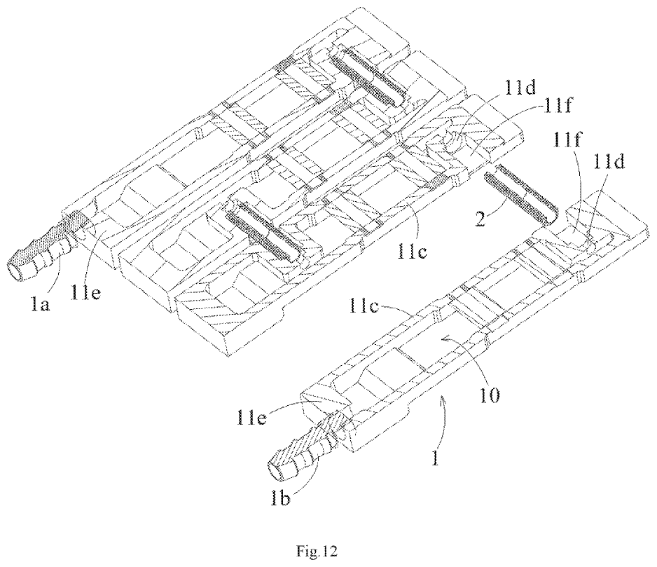

As shown in FIG. 12, a connection hole 11d connected to the inner chamber 10 and a receiving slot 11f connected to the connection hole 11d are formed in the side wall 11c of the liquid cooling plate 1. A part of the flexible tube 2 is accommodated in the receiving slot 11f and the end of the flexible tube 2 is sealingly connected to the connection hole 11d of the liquid cooling plate 1.

As shown in FIG. 12, the top of the receiving slot 11f is open and extends a predetermined length along the axial direction of the connection hole 11d, which is not less than one-third or one-half of the width of the liquid cooling plate 1 in the transverse direction X.

Compared with the liquid cooling module of the connector shown in FIGS. 1-9, the liquid cooling module of the connector shown in FIGS. 10-12 can increase the length and elastic deformation space of the flexible tube 2, allowing adjacent liquid cooling plates 1 to have greater floating amount and smaller floating force relative to each other.

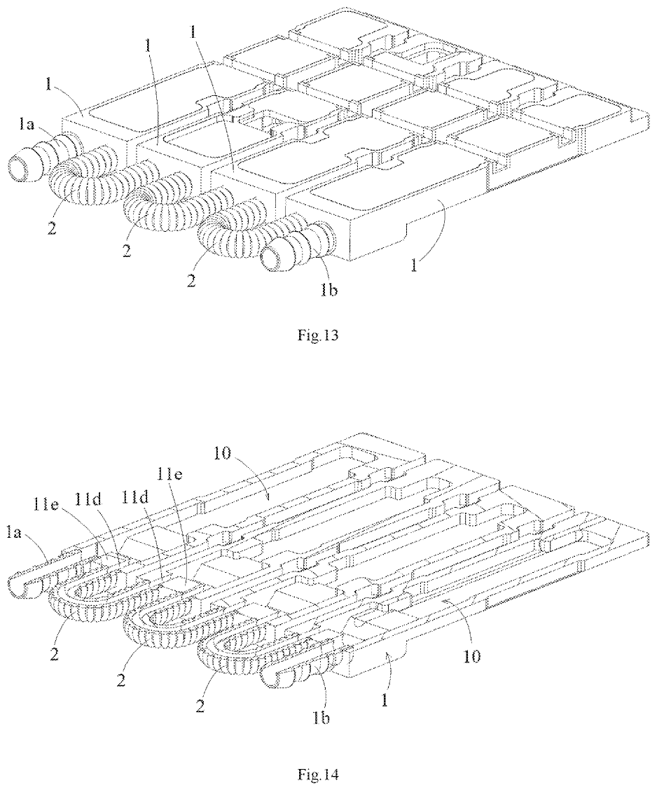

Another exemplary embodiment of a liquid cooling module will now be described with reference to FIGS. 13-14. The difference between the liquid cooling module of the connector shown in FIG. 13-14 and the liquid cooling module of the connector shown in FIGS. 1-9 mainly lies in the structure of the liquid cooling plate 1. Other technical features are basically the same as those of the liquid cooling module of the connector shown in FIGS. 1-9.

As shown in FIG. 14, the liquid cooling plate 1 has two end walls 11e opposite each other in the longitudinal direction Y perpendicular to the transverse direction X. A flexible tube 2 is connected between the end walls 11e of any two adjacent liquid cooling plates 1, and the flexible tube 2 is bent into a U-shape. A connection hole 11d is formed in the end wall 11e of one end of the liquid cooling plate 1, which is connected to its inner chamber 10. The end of the flexible tube 2 is inserted into the connection hole 11d of the liquid cooling plate 1 and sealingly connected to it. The end of the flexible tube 2 is sealingly connected to the connection hole 11d of the liquid cooling plate 1 through sealant or sealingly welded to the connection hole 11d of the liquid cooling plate 1.

Compared with the liquid cooling modules of the connectors shown in FIGS. 1-12, the liquid cooling module of the connector shown in FIGS. 13-14 can increase the total length and elastic deformation space of the flexible tube 2, allowing adjacent liquid cooling plates 1 to have greater floating amount and smaller floating force relative to each other.

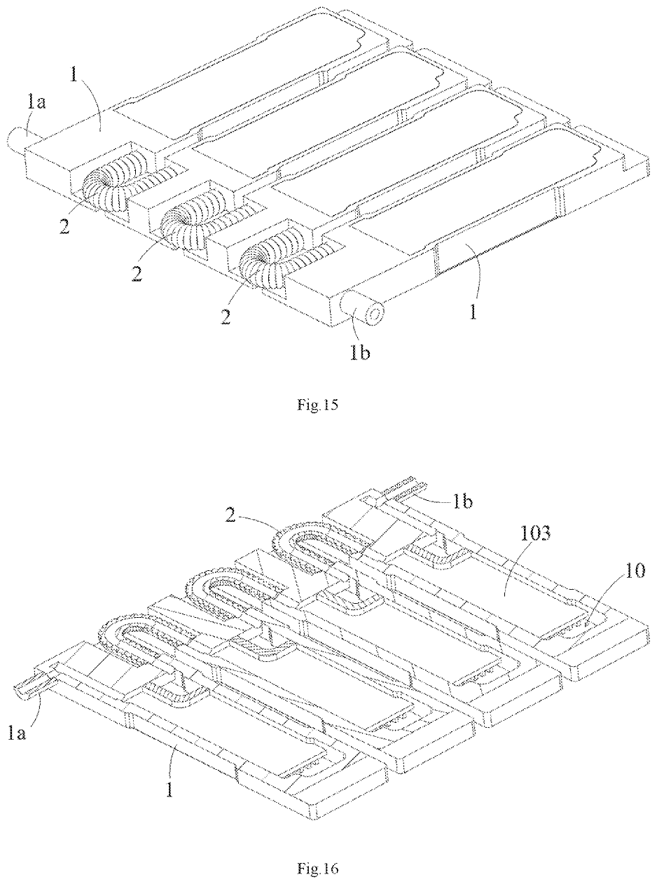

Another exemplary embodiment of a liquid cooling module will now be described with reference to FIGS. 15-17. The difference between the liquid cooling module of the connector shown in FIGS. 15-17 and the liquid cooling module of the connector shown in FIGS. 1-9 mainly lies in the structure of the liquid cooling plate 1. Other technical features are basically the same as those of the liquid cooling module of the connector shown in FIGS. 1-9.

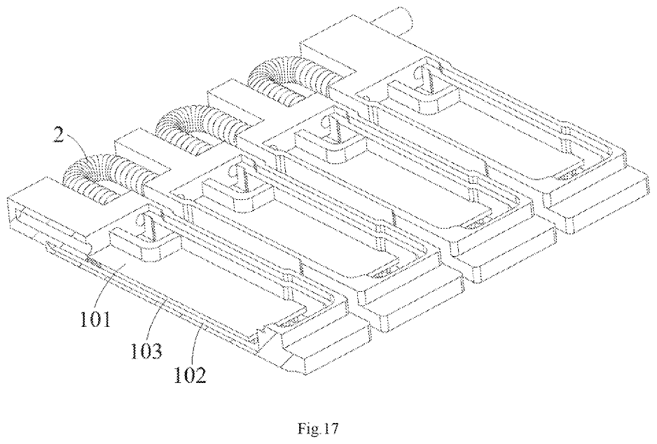

As shown in FIG. 17, the liquid cooling plate 1 has a partition plate 103 that divides its inner chamber 10 into an upper chamber 101 and a lower chamber 102. The inner chamber 10 of the liquid cooling plate 1 has front and rear ends opposite each other in the longitudinal direction Y of the liquid cooling plate 1. The upper chamber 101 and lower chamber 102 of the liquid cooling plate 1 are connected to each other at the front end of the inner chamber 10, and are separated from each other at the rear end of the inner chamber 10. One end of the flexible tube 2 is connected to the rear end of the upper chamber 101 of one of the adjacent two liquid cooling plates 1, and the other end is connected to the rear end of the lower chamber 102 of the other of the adjacent two liquid cooling plates 1.

As shown in FIGS. 15-16, one of the inlet pipe joint 1a and the outlet pipe joint 1b is connected to the rear end of the upper chamber 101 of one of the outermost liquid cooling plates 1 among the multiple liquid cooling plates 1; the other of the inlet pipe joint 1a and the outlet pipe joint 1b is connected to the rear end of the lower chamber 102 of the other of the outermost liquid cooling plates 1 among multiple liquid cooling plates 1.

As shown in FIGS. 15-17, the flexible tube 2 is connected to the end wall of the rear end of the liquid cooling plate 1, and the inlet pipe joint 1a and the outlet pipe joint 1b are located on the outer side of the side walls of the rear ends of the liquid cooling plates 1.

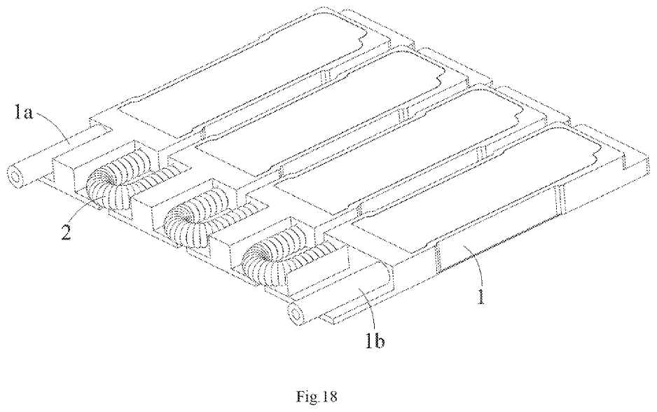

Another exemplary embodiment of a liquid cooling module will now be described with reference to FIG. 18. The difference between the liquid cooling module of the connector shown in FIG. 18 and the liquid cooling module of the connector shown in FIGS. 15-17 is only the position of the inlet pipe joint 1a and the outlet pipe joint 1b. Other technical features are basically the same as those of the liquid cooling module of the connector shown in FIGS. 15-17, which can be referred to as the liquid cooling module of the connector shown in FIGS. 15-17.

As shown in FIG. 18, the inlet pipe joint 1a and the outlet pipe joint 1b are located on the outer side of the end walls of the rear ends of the liquid cooling plates 1.

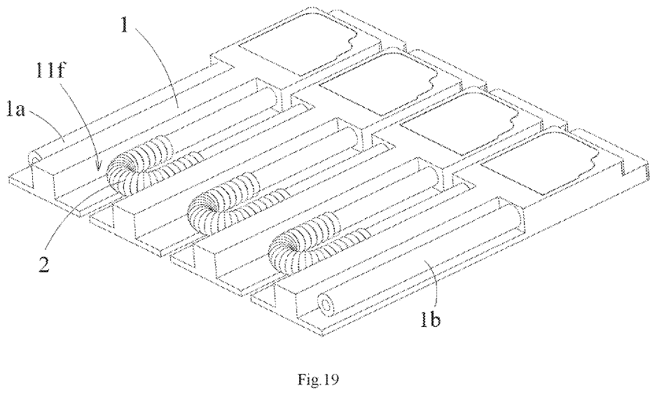

Another exemplary embodiment of a liquid cooling module will now be described with reference to FIGS. 19-21. The difference between the liquid cooling module of the connector shown in FIGS. 19-21 and the liquid cooling module of the connector shown in FIGS. 1-9 mainly lies in the structure of the liquid cooling plate 1. Other technical features are basically the same as those of the liquid cooling module of the connector shown in FIGS. 1-9.

As shown in FIG. 19, a receiving slot 11f is formed on the top wall of the liquid cooling plate 1. The top and sides of the receiving slot 11f are open and extend along the longitudinal direction Y of the liquid cooling plate 1 from the rear end to the front end. The flexible tube 2, inlet pipe joint 1a, and outlet pipe joint 1b are accommodated in the receiving slots 11f of the liquid cooling plates 1.

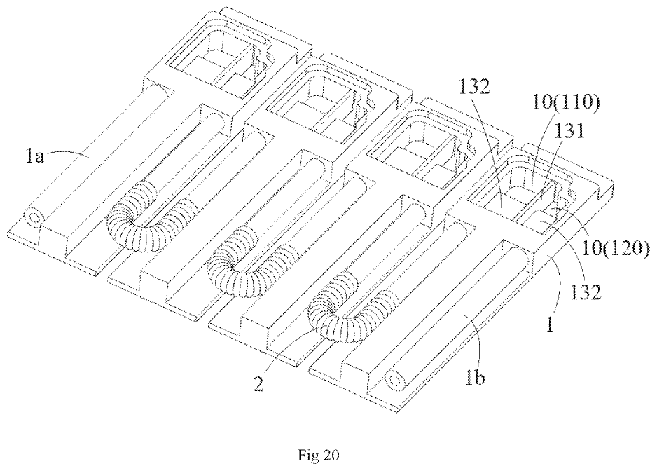

As shown in FIGS. 19-20, the flexible tube 2 extends a predetermined length along the longitudinal direction Y of the liquid cooling plate 1, and the predetermined length is not less than one-third or one-half of the length of the liquid cooling plate 1 in the longitudinal direction Y.

Compared with the liquid cooling module of the connector shown in FIGS. 1-9, the liquid cooling module of the connector shown in FIGS. 19-21 can increase the total length and elastic deformation space of the flexible tube 2, allowing adjacent liquid cooling plates 1 to have greater floating amount and smaller floating force relative to each other.

As shown in FIG. 20, the liquid cooling plate 1 has a vertical partition plate 131 that divides its inner chamber 10 into a left chamber 110 and a right chamber 120, which are connected to each other at the front end of the liquid cooling plate 1. One end of flexible tube 2 is connected to the left chamber 110 of one of the adjacent liquid cooling plates 1, and the other end is connected to the right chamber 120 of the other of the adjacent liquid cooling plates 1.

As shown in FIG. 20, one of the inlet pipe joint 1a and the outlet pipe joint 1b is connected to the left chamber 110 of one of the outermost liquid cooling plates 1 among the multiple liquid cooling plates 1. The other of the inlet pipe joint 1a and the outlet pipe joint 1b is connected to the right chamber 120 of the other of the outermost liquid cooling plates 1 among multiple liquid cooling plates 1.

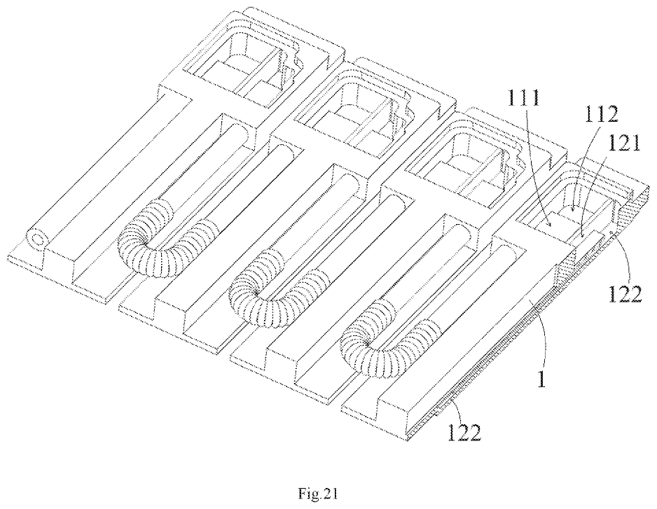

As shown in FIG. 20, the liquid cooling plate 1 also has a horizontal partition plate 132. The horizontal partition plate 132, as shown in FIG. 21, divides its left chamber 110 into a left upper chamber 111 and a left lower chamber 112, and divides its right chamber 120 into a right upper chamber 121 and a right lower chamber 122. The left upper chamber 111 and the left lower chamber 112 are connected to each other at the rear end of the liquid cooling plate 1, and the right upper chamber 121 and the right lower chamber 122 are connected to each other at the rear end of the liquid cooling plate 1. One end of flexible tube 2 is connected to the left upper chamber 111 of one of the adjacent liquid cooling plates 1, and the other end is connected to the right upper chamber 121 of the other of the adjacent liquid cooling plates 1.

One of the inlet pipe joint 1a and the outlet pipe joint 1b is connected to the left upper chamber 111 of one of the outermost liquid cooling plates 1 among the multiple liquid cooling plates 1. The other of the inlet pipe joint 1a and the outlet pipe joint 1b is connected to the right upper chamber 121 of the other of the outermost liquid cooling plates 1 among multiple liquid cooling plates 1.

It should be appreciated for those skilled in this art that the above embodiments are intended to be illustrative, and not restrictive. For example, many modifications may be made to the above embodiments by those skilled in this art, and various features described in different embodiments may be freely combined with each other without conflicting in configuration or principle.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

As used herein, an element recited in the singular and proceeded with the word “a” or “an” should be understood as not excluding plural of said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

1. A liquid cooling module, comprising:
a plurality of liquid cooling plates arranged in parallel in a transverse direction, each liquid cooling plate has an inner chamber accommodating a cooling liquid; and
a plurality of flexible tubes connected between any two adjacent liquid cooling plates, the inner chambers of any two adjacent liquid cooling plates are connected together by the flexible tubes, the liquid cooling plates are connected via the flexible tubes and have an inlet pipe joint and an outlet pipe joint connected to their inner chambers, so as to form a cooling circuit from the inlet pipe joint to the outlet pipe joint.

2. The liquid cooling module of claim 1, wherein each liquid cooling plate has two opposite side walls in the transverse direction, at least one flexible tube is connected between the side walls of any two adjacent liquid cooling plates.

3. The liquid cooling module of claim 2, wherein the inlet pipe joint is formed on one outermost liquid cooling plate of the plurality of liquid cooling plates, and the outlet pipe joint is formed on an other outermost liquid cooling plate of the plurality of liquid cooling plates.

4. The liquid cooling module of claim 3, wherein each liquid cooling plate has two end walls opposite each other in a longitudinal direction perpendicular to the transverse direction, the inlet pipe joint is formed on an outer side of one end wall of the one outermost liquid cooling plate, and the outlet pipe joint is formed on an outer side of one end wall of the other outermost liquid cooling plate.

5. The liquid cooling module of claim 2, wherein at least one flexible tube extends in a straight line along the transverse direction or in a straight line along a direction inclined at a predetermined angle to the transverse direction.

6. The liquid cooling module of claim 2, wherein a connection hole is formed in at least one side wall of at least one liquid cooling plate to communicate with the inner chamber of the at least one liquid cooling plate, an end of one flexible tube is inserted into, and sealingly connected to, the connection hole of the at least one liquid cooling plate.

7. The liquid cooling module of claim 6, wherein the end of the one flexible tube is sealingly connected to the connection hole of the at least one liquid cooling plate through a sealant or is sealingly welded to the connection hole of the at least one liquid cooling plate.

8. The liquid cooling module according to claim 1, wherein at least one flexible tube is a corrugated tube or a thin-walled hose.

9. The liquid cooling module of claim 2, wherein two flexible tubes are connected between the side walls of any two adjacent liquid cooling plates, one of the two flexible tubes is adjacent to one end of the two adjacent liquid cooling plates and an other of the two flexible tubes is adjacent to an other end of the two adjacent liquid cooling plates.

10. The liquid cooling module of claim 2, wherein each liquid cooling plate includes a base having a top opening and formed with the inner chamber of the respective liquid cooling plate, and a top cover sealingly installed into the top opening of the respective base, the side walls of each liquid cooling plate are side walls of each base, at least one flexible tube is connected between the side walls of the bases of two adjacent liquid cooling plates.

11. The liquid cooling module of claim 10, wherein a contact protrusion is formed at a bottom of each base, each contact protrusion protrudes into a connector housing through a window on the connector housing and thermally contacts a mating connector inserted into the connector housing.

12. The liquid cooling module of claim 11, wherein a groove extending in the transverse direction is formed on a top surface of each top cover, one elastic clip is installed in the groove of at least one top cover such that at least one liquid cooling plate is locked onto a top wall of the connector housing through the one elastic clip installed in the groove of at least one top cover.

13. The liquid cooling module of claim 12, further comprising a plurality of elastic clips respectively installed into the respective grooves of each liquid cooling plates, the elastic clips lock the liquid cooling plates onto the top wall of the connector housing and apply a predetermined pressing force on the liquid cooling plates to ensure reliable thermal contact between the liquid cooling plates and a plurality of mating connectors inserted into the connector housing.

14. The liquid cooling module of claim 13, wherein two grooves formed on the top cover of each liquid cooling plate are spaced opposite each other in a longitudinal direction, each elastic clip includes a pair of elastic crossbeams respectively accommodated in two grooves, a pair of longitudinal beams, one longitudinal beam is connected between one end of each pair of elastic crossbeams, and an other longitudinal beam is connected between an other end of each pair of elastic crossbeams, and a plurality of elastic hooks respectively formed on the pair of longitudinal beams, each elastic hook engages with one slot on the connector housing.

15. The liquid cooling module of claim 2, wherein a connection hole connected to the inner chamber and a receiving slot connected to the connection hole are formed in the side wall of at least one liquid cooling plate, a part one flexible tube is accommodated in the receiving slot and an end of the one flexible tube is sealingly connected to the connection hole of the at least one liquid cooling plate.

16. The liquid cooling module of claim 15, wherein a top of the receiving slot of the at least one liquid cooling plate is open and extends a predetermined length along an axial direction of the connection hole of the at least one liquid cooling plate, the predetermined length is not less than one-third or one-half of a width of the at least one liquid cooling plate in the transverse direction.

17. The liquid cooling module of claim 1, wherein each liquid cooling plate has two end walls opposite each other in a longitudinal direction perpendicular to the transverse direction, one flexible tube is connected between the end walls of any two adjacent liquid cooling plates, at least one flexible tube connected between the end walls of any two adjacent liquid cooling plates is bent into a U-shape.

18. The liquid cooling module of claim 17, wherein a connection hole is formed in the end wall of one end of at least one liquid cooling plate to communicate with the inner chamber of the at least one liquid cooling plate, an end of one flexible tube is inserted into the connection hole of the at least one liquid cooling plate and is sealingly connected to the connection hole of the at least one liquid cooling plate.

19. The liquid cooling module of claim 18, wherein the end of the one flexible tube is sealingly connected to the connection hole of the at least one liquid cooling plate through a sealant or is sealingly welded to the connection hole of the at least one liquid cooling plate.

20. The liquid cooling module of claim 1, wherein each liquid cooling plate has a partition plate, each partition plate divides the inner chamber of one liquid cooling plate into an upper chamber and a lower chamber, the inner chamber of each liquid cooling plate has a front end and a rear end opposite each other in a longitudinal direction of each liquid cooling plate, each upper chamber and each lower chamber of one liquid cooling plate are connected to each other at a front end of the inner chamber of the respective liquid cooling plate, one end of one flexible tube is connected to a rear end of the upper chamber of one liquid cooling plate of adjacent liquid cooling plates, and an other end of the one flexible tube is connected to the rear end of the lower chamber of an other liquid cooling plate of adjacent liquid cooling plates.

21. The liquid cooling module of claim 20, wherein one of the inlet pipe joint and the outlet pipe joint is connected to the rear end of the upper chamber of one outermost liquid cooling plate of the plurality of liquid cooling plates, and the other of the inlet pipe joint and the outlet pipe joint is connected to the rear end of the lower chamber of an other outermost liquid cooling plate of the plurality of liquid cooling plates.

22. The liquid cooling module of claim 20, wherein one flexible tube is connected to an end wall of the rear end of at least one liquid cooling plate, and the inlet pipe joint and the outlet pipe joint are located on an outer side of the end wall of the rear end of the at least one liquid cooling plate or a side wall of the rear end of the at least one liquid cooling plate.

23. The liquid cooling module of claim 1, wherein a receiving slot is formed on a top wall of each liquid cooling plate, a top and sides of each receiving slot are open and extend along a longitudinal direction of the liquid cooling plates from a rear end to a front end, the flexible tubes, the inlet pipe joint, and the outlet pipe joint are accommodated in the receiving slots of the liquid cooling plates.

24. The liquid cooling module of claim 23, wherein at least one flexible tube extends a predetermined length along the longitudinal direction, the predetermined length is not less than one-third or one-half of a length of at least one liquid cooling plate in the longitudinal direction.

25. The liquid cooling module of claim 23, wherein each liquid cooling plate has a vertical partition plate, each vertical partition plate divides the inner chamber of one liquid cooling plate into a left chamber and a right chamber, each left chamber and each right chamber of one liquid cooling plate are connected to each other at a front end of the respective liquid cooling plate, one end of one flexible tube is connected to the left chamber of one liquid cooling plate of adjacent liquid cooling plates, and an other end of the one flexible tube is connected to the right chamber of an other liquid cooling plate of adjacent liquid cooling plates.

26. The liquid cooling module of claim 25, wherein one of the inlet pipe joint and the outlet pipe joint is connected to the left chamber of one outermost liquid cooling plate of the plurality of liquid cooling plates, and the other of the inlet pipe joint and the outlet pipe joint is connected to the right chamber of an other outermost liquid cooling plate of the plurality of liquid cooling plates.

27. The liquid cooling module of claim 25, wherein each liquid cooling plate has a horizontal partition plate, each horizontal partition plate divides each left chamber of one liquid cooling plate into a left upper chamber and a left lower chamber, and divides each right chamber of one liquid cooling plate into a right upper chamber and a right lower chamber, each left upper chamber and each left lower chamber of one liquid cooling plate are connected to each other at the rear end of the respective liquid cooling plate, and each right upper chamber and each right lower chamber are connected to each other at the rear end of the respective liquid cooling plate, one end of the one flexible tube is connected to the left upper chamber of the one liquid cooling plate of adjacent liquid cooling plates, and an other end of the one flexible tube is connected to the right upper chamber of the other liquid cooling plate of adjacent liquid cooling plates.

28. The liquid cooling module of claim 27, wherein one of the inlet pipe joint and the outlet pipe joint is connected to the left upper chamber of one outermost liquid cooling plate of the plurality of liquid cooling plates, and the other of the inlet pipe joint and the outlet pipe joint is connected to the right upper chamber of an other outermost liquid cooling plate of the plurality of liquid cooling plates.

29. A connector, comprising:
a connector housing having a plurality of insertion cavities arranged side by side in a transverse direction of the connector housing; and
a liquid cooling module including a plurality of liquid cooling plates and a plurality of flexible tubes, the liquid cooling plates are arranged in parallel in the transverse direction, each liquid cooling plate has an inner chamber accommodating a cooling liquid, the flexible tubes are connected between any two adjacent liquid cooling plates, the inner chambers of any two adjacent liquid cooling plates are connected together by the flexible tubes, the liquid cooling plates are connected via the flexible tubes and have an inlet pipe joint and an outlet pipe joint connected to their inner chambers, so as to form a cooling circuit from the inlet pipe joint to the outlet pipe joint, the liquid cooling module is installed on a top wall of the connector housing, a plurality of windows corresponding to the insertion cavities are formed on the top wall of the connector housing, and contact protrusions of the liquid cooling plates respectively protrude into the insertion cavities through respective windows, the contact protrusions thermally contact a plurality of mating connectors inserted into the insertion cavities.

30. The connector of claim 29, further comprising a plurality of electrical connection modules respectively installed in the insertion cavities of the connector housing, the electrical connection modules respectively mate with the mating connectors inserted into the insertion cavities to achieve electrical connection between the connector and the mating connectors.

31. The connector of claim 29, wherein the connector housing has a front end and a rear end opposite in a longitudinal direction of the connector housing, at least one insertion cavity has a front port and a rear end wall opposite in the longitudinal direction, at least one mating connector is inserted into the at least one insertion cavity from the front port of the at least one insertion cavity.

32. The connector of claim 31, wherein a contact spring is installed on a peripheral wall of the front port of the at least one insertion cavity, the contact spring electrically contacts an outer shielding shell of the at least one mating connector inserted into the at least one insertion cavity from the front port of the at least one insertion cavity.

33. The connector of claim 31, wherein a positioning step is formed at a bottom of a rear end of at least one liquid cooling plate, the positioning step of the least one liquid cooling plate is pressed against the rear end wall along the longitudinal direction.
